(19) United States
(12) Patent Application Publication
(10) Pub. No.: US 2025/0140742 A1
(43) Pub. Date: May 1, 2025

(54) PACKAGE LAYOUTS UTILIZING NON-RECTANGULAR PERIPHERAL CHIPS

(71) Applicant: NVIDIA Corp., Santa Clara, CA (US)

(72) Inventors: Benjamin Giles Lee, Ridgefield, CT (US); Thomas Hastings Greer, III, Chapel Hill, NC (US)

(73) Assignee: NVIDIA Corp., Santa Clara, CA (US)

(21) Appl. No.: 18/494,495

(22) Filed: Oct. 25, 2023

(51) Int. Cl. H01L 25/065; H01L 23/498; H01L 25/18

(52) U.S. Cl. CPC H01L 25/0652; H01L 23/49838; H01L 25/18; H01L 2225/06555

(57) ABSTRACT

A circuit package includes a central chip and multiple input/output (IO) chips disposed along a periphery of the central chip, wherein at least some of the IO chips being non-rectangular and extending into corner regions of the periphery. The IO chips may have non-rectangular patterned areas in the shape of isosceles trapezoids, right trapezoids, and stepped tables, for example.

### BACKGROUND

Conventional chip package layouts dispose rectangular input/output (IO) chips around the periphery of a central chip. These layouts either leave the corner regions of the central chip periphery unoccupied by circuitry, or else they dilate the package (e.g., increase the interposer spacing between the central chip and the IO chips) to increase the available package boundary for locating package IO pins.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1A-FIG. 1C depict conventional circuit package designs.

FIG. 2A-FIG. 2D depict embodiments of a circuit package that includes non-rectangular chips extending into corner regions of the periphery of a central chip.

FIG. 3A depicts an embodiment wherein the central chip is a graphics processing unit or switch and the IO chips are optical transceiver chips.

FIG. 3B depicts a conventional layout to achieve an equivalent length of package boundary for the package IO pins as the embodiment depicted in FIG. 3A.

FIG. 3C depicts an embodiment utilizing silicon bridges to interface the central chip with optical transceivers.

FIG. 4 depicts an embodiment of a reticle for use in fabricating chips comprising an isosceles trapezoid non-rectangular patterned area.

FIG. 5 depicts a mask pattern produced on a wafer by stepping the reticle of FIG. 4 across the wafer in conventional manners.

FIG. 6 depicts aspects of a circuit manufacturing process in one embodiment.

FIG. 7 depicts a staggered stepping of an isosceles trapezoid-based reticle across a wafer in one embodiment.

FIG. 8 depicts wafer patterning resulting from staggered stepping of an isosceles trapezoid-based reticle across the wafer.

FIG. 9 depicts a staggered stepping of a stepped table-based reticle across a wafer in one embodiment.

FIG. 10 depicts wafer patterning resulting from staggered stepping of a stepped table-based reticle across the wafer.

FIG. 11 depicts aspects of a circuit manufacturing process in one embodiment.

FIG. 12 depicts a non-staggered stepping of a right trapezoid-based reticle across a wafer in one embodiment.

### DETAILED DESCRIPTION

Mechanisms are disclosed for the packaging of multiple integrated circuits onto a common substrate (e.g., silicon interposer, glass carrier, organic substrate) using solder attachments or wafer-scale integration methods. The disclosed mechanisms may enable expanded IO and pin capacity at the circuit package periphery and may enable smaller overall package sizes.

In many circuit packages, edge connection density at the interface between a central chip and peripheral chips is a constrained resource. This resource may be especially constrained when integrating IO chips tiled around the perimeter of a silicon interposer due to interposer area and trace length limitations.

A silicon interposer provides an interface between different semiconductor chips within a package. It is a layer of silicon comprising a network of wiring or interconnects, allowing multiple chips to be interconnected. The interposer provides a shorter, faster, and more efficient connection between chips compared to traditional wire bonding methods and enables high-bandwidth communication and data transfer between chips, reducing power consumption and improving overall performance in electronic devices.

In many implementations, such as those utilizing a silicon interposer, the on-package connection/bandwidth density between the central circuit (e.g., a processor chip) and the peripheral IO chips may need to match the off-package connection/bandwidth density output to the package periphery from the IO chips. Meeting this requirement may be challenging for electrical IO, and may be particularly problematic for optical IO because the factors that contribute to electrical interface density are fundamentally different than the factors that contribute to the optical interface density (fiber pitch, multiplexing parallelism, optical connector overhead, etc.).

The disclosed mechanisms may thus be particularly impactful for optical transceivers integrated on a silicon interposer around switch or processor chips. More generally the disclosed mechanisms are applicable to chips and packages utilizing one or both optical and electrical IO, and for integration onto any chip package, such as a silicon interposer, organic substrate, or glass carrier.

The disclosed techniques utilize non-rectangular IO chips that extend into corners of the circuit package that are un-utilized in conventional packages. By taking advantage of the corner sections, the IO at the outer perimeter may be expanded with respect to the IO at the inner perimeter, relaxing bandwidth density for off-package communications.

Conventionally, non-rectangular die may be fabricated using standard lithography tools with certain loss of efficiency (wasted space, added cost). The disclosed techniques apply a design layout that mitigates or eliminates this loss of efficiency. In some cases the techniques are enabled by augmentation of the lithography stepper to allow offsets and/or overlaps between adjacent exposure regions. Once fabricated, the non-rectangular die may be singulated using laser dicing or other well-known methods.

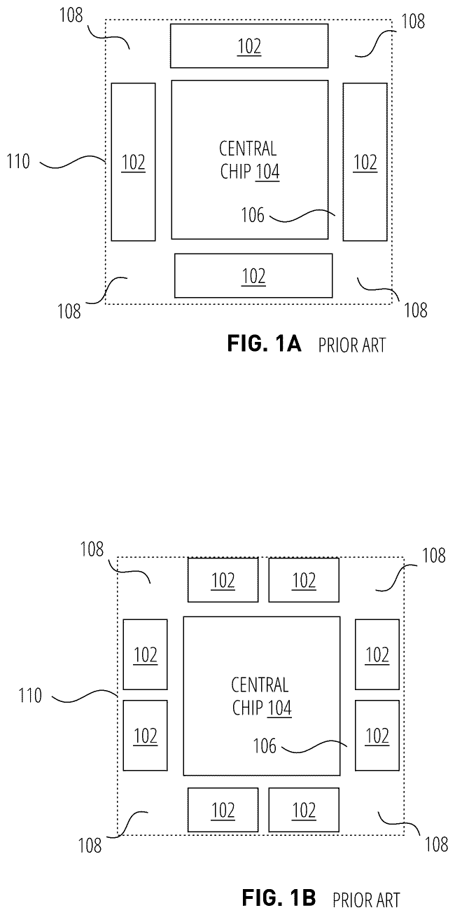

FIG. 1A-FIG. 1C depict conventional circuit package designs. The package comprises multiple IO chips 102 arranged along the peripheral sides of a central 104. Although depicted as a single chip or chip package, it should be understood that the central 104 represents one or multiple chips that interface to the surrounding IO chips 102.

In the examples depicted in FIG. 1A-FIG. 1C, the central 104 (or chips) interfaces with the IO chips 102 via an interposer 106. Other implementations may utilized silicon bridges (e.g., silicon bridge chips or dense circuit patterns formed within the substrate) to implement these interfaces. The corner regions 108 of the periphery of the central 104 are unoccupied by circuitry due to the constraints and complexity of routing to those areas when the rectangular packages of the IO chips 102 are extended into the corner regions 108. The available locations for pins (e.g., IO ports) on the package boundary 110 are limited to the length of the periphery of the central 104.

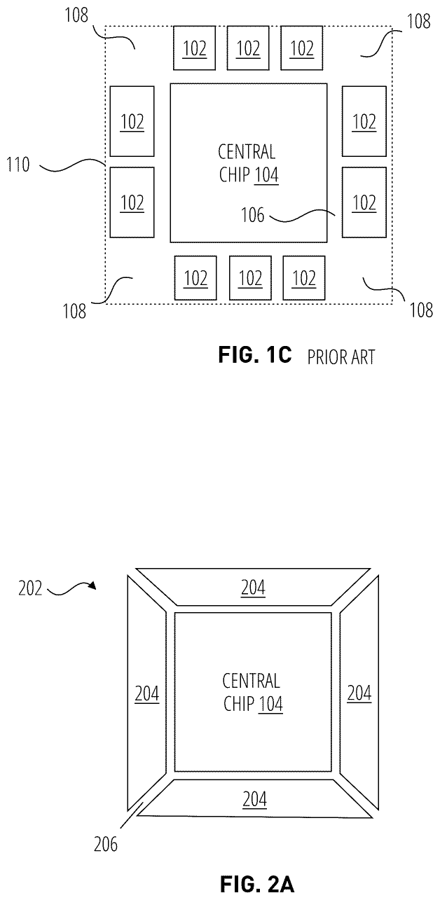

FIG. 2A-FIG. 2D depict embodiments of a circuit package 202 that includes a central 104, and a plurality of input/output chips (IO chips 204) disposed along a periphery of the central 104, at least some of the IO chips 204 being non-rectangular and extending into corner regions 206 of the periphery.

In the embodiment depicted in FIG. 2A, at least some of the non-rectangular IO chips 204 are isosceles trapezoids. In the embodiments depicted in FIG. 2B and FIG. 2C, at least some of the non-rectangular IO chips 204 are right trapezoids. In the embodiment of FIG. 2C, one or more rectangular chips 208 is disposed on the periphery between the right trapezoid chips.

In the embodiment depicted in FIG. 2D, at least some of the non-rectangular IO chips 204 are stepped tables.

Other technical features, such as the routing of connections from the central 104 to the IO chips 204 via an interposer or silicon bridge, may be readily apparent to one skilled in the art from this description and the depicted examples.

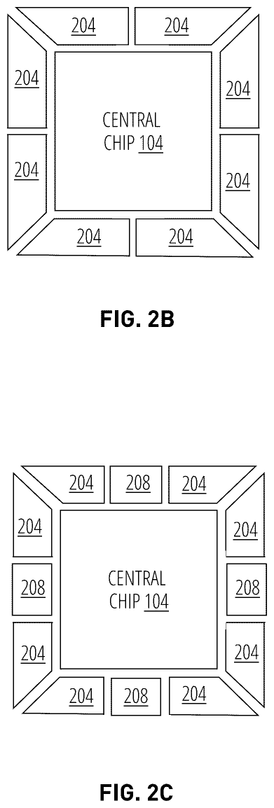

In particular embodiments (see FIG. 3A) the central 104 is a graphics processing unit or switch and the IO chips are optical transceivers 302 comprising an electro-optical interface 304 to the central 104 and package IO ports 306 (e.g., optical couplers) disposed at the package boundary. The circuit package may further include a silicon interposer 308 interfacing the central 104 to the optical transceivers 302. In comparison to conventional package layouts (see FIG. 3B), the same length of package boundary for the package IO ports 306 is achieved with a smaller overall package size and a smaller trace length (d) across the silicon interposer 308.

In one embodiment, the optical transceivers 302 comprise optical waveguides 312 between the electro-optical interfaces 304 and the package IO ports 306, which are optical couplers. In one embodiment, the electro-optical interfaces 304 and the optical transceivers 302 may be implemented as separate chips. In another embodiment, the electro-optical interfaces 304 are implemented as part of the optical transceiver 302 chips. In one particular embodiment, the electro-optical interfaces 304 are implemented as separate chips from the optical transceivers 302, which consist primarily of optical waveguides 312; the electro-optical interface 304 chips are mounted on the optical transceiver 302 chips, and any active optical components (e.g., light modulators and/or photo-diodes, actively generating signals, as opposed to merely propagating signals generated elsewhere) of the optical transceiver 302 chips are disposed at the mounting interface of the electro-optical interface 304 chip to the optical transceiver 302 chip. In another particular embodiment, the electro-optical interfaces 304 are again implemented as separate chips from the optical transceivers 302, which implement only passive optical waveguides 312; the electro-optical interface 304 chips are mounted on the optical transceiver 302 chips and comprise the active optical and electrical components.

FIG. 3C depicts an embodiment utilizing silicon bridges 310 rather than a silicon interposer 308 between the central 104 and the optical transceivers 302. The silicon bridges 310 may be implemented using any of a number of mechanisms known in the art. The optical transceivers 302 primary comprise optical waveguide 312 between the electro-optical interfaces 304 (which may be separate chips from the non-rectangular optical transceiver 302 chips) and the optical couplers (306) at the outer periphery of the optical transceivers 302.

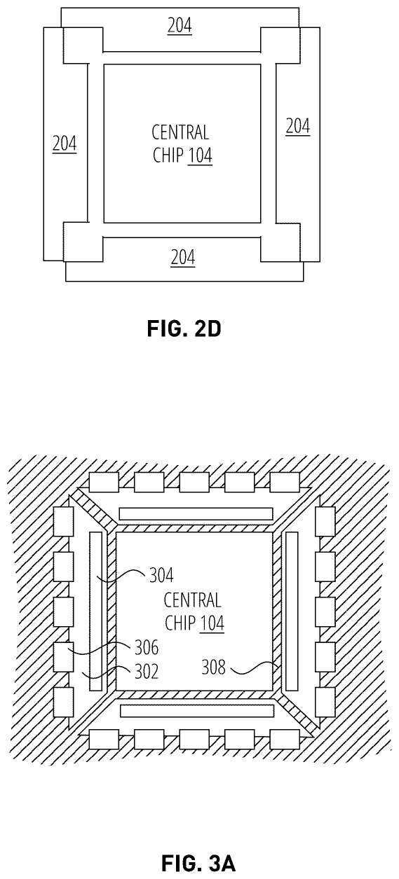

FIG. 4 depicts an embodiment of a reticle for use in fabricating chips comprising an isosceles trapezoid non-rectangular patterned area. “Isosceles trapezoid” refers to a trapezoid comprising two parallel sides (the bases) of different lengths and two non-parallel sides of equal length. The black regions of the reticle are areas that do not pass light to the underlying wafer and thus produce no circuit patterning on the wafer.

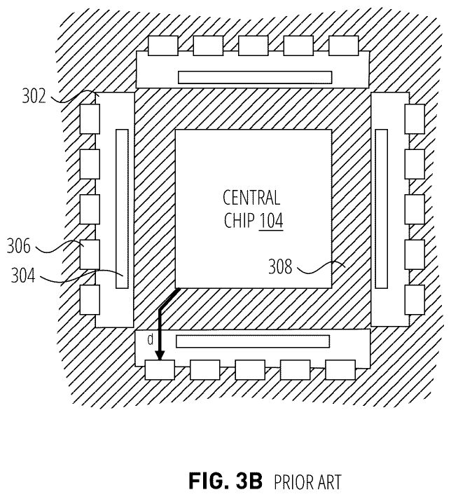

FIG. 5 depicts a mask pattern produced on a wafer by stepping the reticle of FIG. 4 across the wafer in conventional manners. The black areas on the wafer remain unpatterned and thus constitute waste of the wafer.

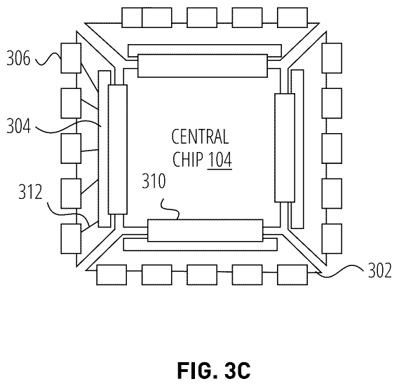

FIG. 6 depicts aspects of a circuit manufacturing process in one embodiment. At block 600, a reticle is stepped across a wafer, where the reticle comprises at least one stacked complementary pair of non-rectangular patterned areas. “Stacked complementary pair” refers to a first such shape on a reticle adjacent to and vertically aligned with an inverted version of said shape on the reticle. In block 602, the reticle is staggered at alternate stepped locations on the wafer. “Alternate stepped locations” refers to every other stop location of a reticle stepper. At each of the stepped locations the wafer is exposed (e.g., to ultraviolet light) to pattern the wafer die at those locations.

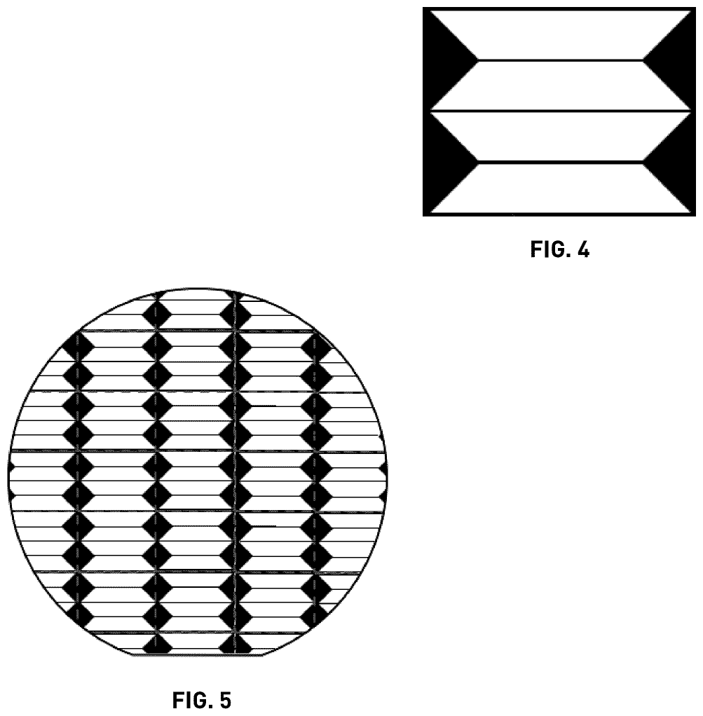

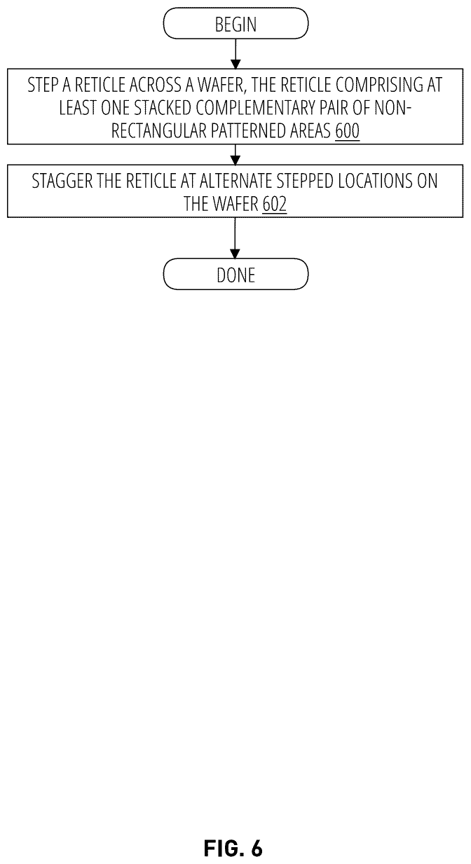

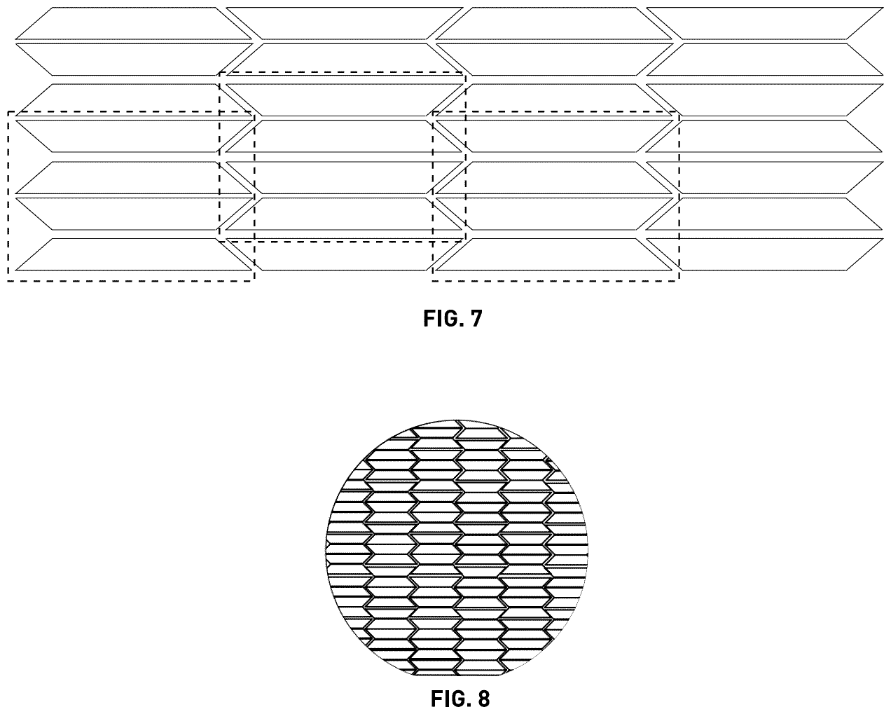

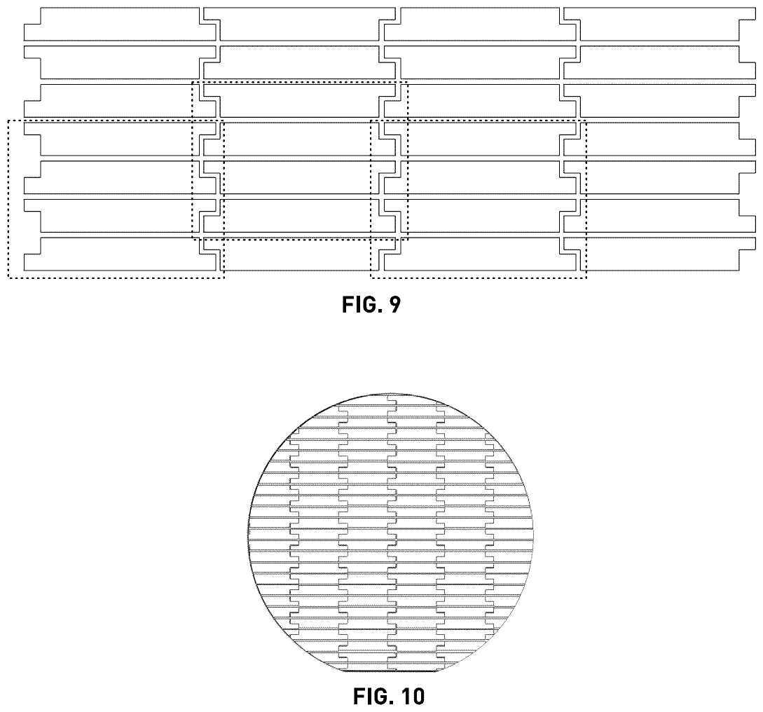

The non-rectangular patterned areas may comprise isosceles trapezoid (FIG. 7) or stepped table (FIG. 9) shapes, for example. The reticle may include two stacked complementary pairs of non-rectangular patterned areas as depicted in the example of FIG. 4. Stepping this reticle in conventional fashion, without staggering, leads to the exposure pattern on the wafer depicted in FIG. 5, which is wasteful (the black areas remain unexposed and un-patterned). By staggering alternate steps of the reticle across the wafer as depicted in FIG. 7 for isosceles trapezoid non-rectangular patterned areas and in FIG. 9 for stepped table non-rectangular patterned areas, the more efficient wafer exposures of FIG. 8 (for isosceles trapezoid-based reticles) and FIG. 10 (for stepped table-based reticles) are achieved. “Stepped table” refers to a shape resulting from replacing the non-parallel sides of an isosceles trapezoid with steps, i.e., by forming a step with an inward right angle turn a distance up from the lower base, followed by an upward right angle turn to the upper base.

The reticle may staggered at the alternate stepped locations by one reticle pattern unit as depicted in FIG. 7, or more generally staggered at the alternate stepped locations by any odd number of reticle pattern units (1, 3, 5, etc.). Other technical features of the process, such as slicing of the wafer into die, may be readily apparent to one skilled in the art without further elaboration.

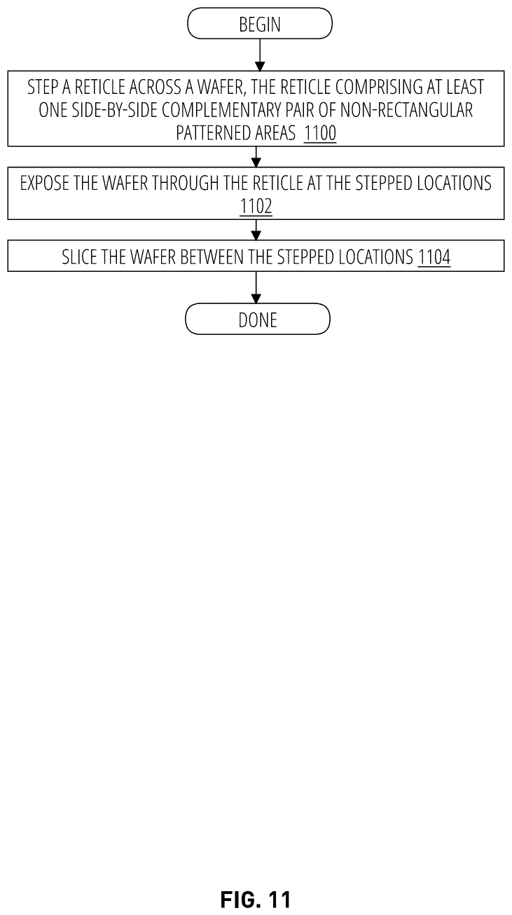

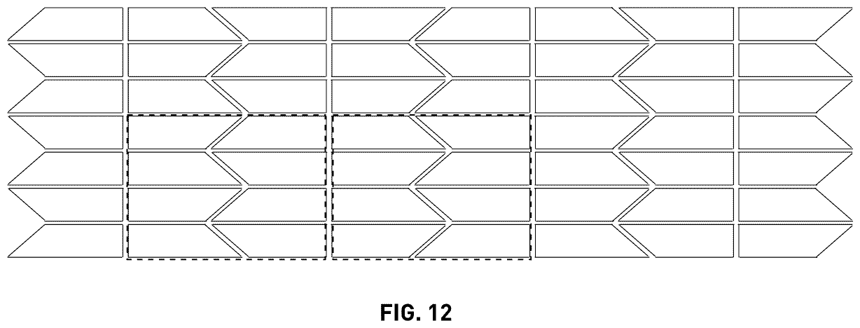

FIG. 11 depicts aspects of a circuit manufacturing process in another embodiment. At block 1100, a reticle is stepped across a wafer, the reticle comprising at least one side-by-side complementary pair of non-rectangular patterned areas.

In this embodiment the side-by-side complementary pairs are pairs of right trapezoids. “Right trapezoid” refers to a trapezoid with two parallel sides (the bases) of different lengths and two non-parallel sides, one of which forms right angles with the bases.

For isosceles trapezoid and stepped table shapes, “side-by-side complementary pair” refers to a first such shape on a reticle adjacent to and horizontally aligned with an inverted version of said shape on the reticle. For right trapezoid shapes, “side-by-side complementary pair” refers to a first such shape on a reticle adjacent to and horizontally aligned with a horizontally-flipped version (mirror image) of said shape on the reticle. In block 1102, the wafer is exposed through the reticle at the stepped locations, and the wafer is then sliced between the stepped locations at block 1104.

The reticle may comprise at least one stacked complementary quad of non-rectangular patterned areas, as depicted in FIG. “Stacked complementary quad” refers to a pair of vertically aligned stacked complementary pairs, 12, where the non-rectangular patterned areas are right trapezoids and a pair of the stacked complementary quads are utilized in the reticle. Staggering of the reticle at alternate stepped locations across the wafer is not utilized due to the efficient utilization of the right angled aspects of the right trapezoids.

### LISTING OF DRAWING ELEMENTS

102 IO chip
104 central
chip
106 interposer
108 corner region
110 package boundary
202 circuit package
204 IO chip
206 corner region
208 rectangular chip
302 optical transceiver
304 electro-optical interface
306 package IO ports
308 silicon interposer
310 silicon bridge
312 optical waveguide
600 block
602 block
1100 block
1102 block
1104 block

Various functional operations described herein may be implemented in logic that is referred to using a noun or noun phrase reflecting said operation or function. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter). For example, an association operation may be carried out by an “associator” or “correlator”. Likewise, switching may be carried out by a “switch”, selection by a “selector”, and so on. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter). Logic symbols in the drawings should be understood to have their ordinary interpretation in the art in terms of functionality and various structures that may be utilized for their implementation, unless otherwise indicated.

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112(f) for that claim element. Accordingly, claims in this application that do not otherwise include the “means for” [performing a function] construct should not be interpreted under 35 U.S.C § 112(f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the invention as claimed. The scope of inventive subject matter is not limited to the depicted embodiments but is rather set forth in the following Claims.

What is claimed is:

1. A circuit manufacturing process comprising:
stepping a reticle across a wafer, the reticle comprising at least one stacked complementary pair of non-rectangular patterned areas; and
staggering the reticle at alternate stepped locations on the wafer.

2. The circuit manufacturing process of claim 1, further comprising exposing the wafer through the reticle at the stepped locations.

3. The circuit manufacturing process of claim 1, wherein the non-rectangular patterned areas are isosceles trapezoids.

4. The circuit manufacturing process of claim 1, wherein the non-rectangular patterned areas are stepped tables.

5. The circuit manufacturing process of claim 1, wherein the reticle comprises two stacked complementary pairs of non-rectangular patterned areas.

6. The circuit manufacturing process of claim 1, wherein the reticle is staggered at the alternate stepped locations by an odd number of reticle pattern units.

7. The circuit manufacturing process of claim 6, wherein the reticle is staggered at alternate stepped locations by one reticle pattern unit.

8. The circuit manufacturing process of claim 6, wherein the reticle is staggered at alternate stepped locations by three reticle pattern units.

9. A circuit manufacturing process comprising:
stepping a reticle across a wafer, the reticle comprising at least one side-by-side complementary pair of non-rectangular patterned areas;
exposing the wafer through the reticle at stepped locations; and
slicing the wafer between the stepped locations.

10. The circuit manufacturing process of claim 9, wherein exposing the wafer through the reticle at stepped locations comprises exposing the wafer to an optical transceiver circuit structure comprising electro-optical interfaces.

11. The circuit manufacturing process of claim 9, the reticle comprising at least one stacked complementary quad of non-rectangular patterned areas.

12. The circuit manufacturing process of claim 11, the reticle comprising a pair of stacked complementary quads of non-rectangular patterned areas.

13. The circuit manufacturing process of claim 9, wherein the non-rectangular patterned areas are right trapezoids.

14. A circuit package comprising:
a central chip; and
a plurality of input/output (IO) chips disposed along a periphery of the central chip, at least some of the IO chips being non-rectangular IO chips and extending into corner regions of the periphery.

15. The circuit package of claim 14, wherein the non-rectangular IO chips comprise optical waveguides coupling electro-optical interface chips to optical coupler ports.

16. The circuit package of claim 15, wherein the electro-optical interface chips are mounted on the non-rectangular IO chips, and the non-rectangular IO chips further comprise active optical components disposed at an interface to the electro-optical interface chips.

17. The circuit package of claim 14, wherein at least some of the non-rectangular IO chips are isosceles trapezoids.

18. The circuit package of claim 14, wherein at least some of the non-rectangular IO chips are right trapezoid chips.

19. The circuit package of claim 18, further comprising one or more rectangular chips disposed between the right trapezoid chips.

20. The circuit package of claim 14, wherein at least some of the non-rectangular IO chips are stepped tables.

21. The circuit package of claim 14, wherein the central chip is a graphics processing unit and the IO chips are optical transceivers.

22. The circuit package of claim 14, wherein the central chip is a switch and the IO chips are optical transceivers.

23. The circuit package of claim 14, further comprising a silicon interposer interfacing the central chip to the IO chips.

24. The circuit package of claim 14, further comprising silicon bridges interfacing the central chip to the IO chips.
